(19) United States
(12) Patent Application Publication
(10) Pub. No.: US 2015/0184295 A1
(43) Pub. Date: Jul. 2, 2015

(54) ATOMIC LAYER DEPOSITION APPARATUS

(71) Applicant: MTS Nanotech Inc., Suwon-si (KR)

(72) Inventor: In Kwon Jeong, Cupertino, CA (US)

(73) Assignee: MTS NANOTECH INC., Suwon-si (KR)

(21) Appl. No.: 14/407,963

(22) PCT Filed: Jun. 19, 2013
(86) PCT No.: PCT/KR2013/005412

§ 371 Date: Dec. 14, 2014

(30) Foreign Application Priority Data
Jun. 20, 2012 (KR) 10-2012-0065954
Jun. 25, 2012 (KR) 10-2012-0068196
Jul. 9, 2012 (KR) 10-2012-0074317
Jul. 23, 2012 (KR) 10-2012-0080232

(51) Int. Cl. C23C 16/455; C23C 16/44

(52) U.S. Cl. CPC C23C 16/45525; C23C 16/45565; C23C 16/4412

(57) ABSTRACT

An apparatus for depositing atomic layers coats first and second reaction layers alternately on a substrate by repeating injection of source precursor and purge gas from a showerhead with the showerhead moving forward and injection of reactant precursor and the purge gas from the showerhead with the showerhead moving backward. The precursors and purge gas injected are exhausted in real time through the showerhead. Mixing of the source and reactant precursors is prevented by the alternate injections of the source and reactant precursors. Throughput is improved by the simultaneous injections of the precursor and the purge gas. By minimizing a moving distance of the showerhead, a footprint is reduced and the apparatus can be used for large size substrates. It is also possible to deposit the atomic layers selectively on a specific selected region.

### CROSS REFERENCE TO RELATED APPLICATION

This application is entitled to the benefit of KR Patent Application Ser. Nos. 10-2012-0065954 filed on Jun. 20, 2012, 10-2012-0068196 filed on Jun. 25, 2012, 10-2012-0074317 filed on Jul. 9, 2012, and 10-2012-0080232 filed on Jul. 23, 2012, which are all incorporated herein by reference.

### FIELD OF THE INVENTION

The invention relates generally to a thin film deposition apparatus, and more particularly to an apparatus and a method for depositing atomic layers on semiconductor substrates.

### BACKGROUND OF THE INVENTION

Atomic layer deposition is widely used to deposit thin films on semiconductor wafers and its application is extended to deposit thin films on CIGS solar cells, Si solar cells and OLED displays. Typical atomic layer deposition process consists of the following four steps.

At the first step, source precursor such as TMA trimethyl-aluminum is injected to the substrate. The source precursor reacts with the surface of the substrate and coats the surface with a first reaction layer.

At the second step, which is a purge step, the source precursor which is adsorbed physically on the surface of the substrate is removed by injecting inert gas such as nitrogen to the substrate.

At the third step, reactant precursor such as H₂O is injected to the substrate. The reactant precursor reacts with the first reaction layer and coats the substrate with a second reaction layer.

At the fourth step, which is the purge step, the reactant precursor which is adsorbed physically on the surface of the substrate is removed by injecting the inert gas. Through the cycle, a single layer of thin film consisting of the first and second reaction layers, for example Al₂O₃ thin film, is deposited on the substrate. To get a thin film with a desired thickness the cycle is repeated.

Deposition speed of the thin film by the atomic layer deposition process is determined by the time required to complete the cycle of the four steps. Therefore the atomic layer deposition has a disadvantage that the deposition speed is slow because the supplies of the source precursor, the purge gas, the reactant precursor and the purge gas must be sequential.

Referring to FIGS. 1 and 2, another ALD (atomic layer deposition) method, so called space-divided ALD, is described. FIGS. 1 and 2 are side and top views of an ALD apparatus according to the space-divided ALD, respectively. In the space-divided ALD, the second, first and second reaction layers are sequentially coated on the substrate 50 by moving the substrate 50 through a shower head 20 having a hole for injecting the reactant precursor 21, a hole for exhaust 22, a hole for injecting the purge gas 23, a hole for exhaust 24, a hole for injecting the source precursor 25, a hole for exhaust 26, a hole for injecting the purge gas 27, a hole for exhaust 28, and a hole for injecting the reactant precursor 29.

The source precursor injected from the hole 25 is exhausted through its neighboring holes for exhaust 24 and 26. The reactant precursor injected from the holes 21 and 29 is exhausted through the respective neighboring holes 22 and 28. The purge gas injected from the hole 23 is exhausted through its neighboring holes for exhaust 22 and 24. The purge gas injected from the hole 27 is exhausted through its neighboring holes for exhaust 27 and 94.

The space-divided ALD has problems that a moving distance of the substrate or the showerhead is long and a footprint of the apparatus is large because the substrate 50 must be moved completely to the opposite side of the showerhead 20 through the showerhead 20 as shown in FIG. 2 in order to get a uniform film thicknesses on both of the edge region 50a and the central region 50b of the substrate 50.

The space-divided ALD also has a problem that the substrate must move back and forth 52 at high speed a distance equal to the widths of the substrate 52w and the showerhead 20w in order to deposit the thin film at high speed.

This problem becomes more remarkable as the widths of the substrate 50w and the showerhead 20w become greater. For example, a minimum moving distance for CIGS solar cell substrate is over 600 mm as its size is 1200 mm×600 mm. For another example, a minimum moving distance for 5.5 generation OLED display substrate is over 1300 mm as its size is 1500 mm×1300 mm.

In addition, the moving speed of the substrate 50 and the design of the showerhead 20 can be also limited because particles can be generated if the source and reactant precursors are mixed during the high speed moving.

In order to prevent mixing of the source and reactant precursors, the showerhead 20 must be disposed as close as possible to the substrate. For example, the gap between the substrate 50 and the showerhead 20 must be less than 1 mm.

When it needs to deposit the atomic layers on a selected region of the substrate, the conventional ALD uses a shadow mask. By placing the shadow mask on the substrate the atomic layers are deposited only on the regions which are not shadowed by the shadow mask. The shadow mask must be replaced periodically because the atomic layers are also deposited on the shadow mask. It is also inconvenient to load and unload the shadow mask to and from the surface of the substrate whenever the substrates are changed.

As described above, ALD requires an apparatus and methods that are designed to provide a short cycle time and a short back and forth moving distance of the substrate or the showerhead. ALD requires an apparatus and methods that are designed such that the source and reactant precursors are not mixed and therefore particles are not generated.

ALD requires also an apparatus and methods that are designed to deposit the atomic layers on selected region of the substrate without using the shadow mask.

### SUMMARY OF THE INVENTION

An atomic layer deposition apparatus and a method according to an embodiment of the invention provide the short cycle time and the short moving distance of the substrate or the showerhead. The atomic layer deposition apparatus and method according to an embodiment of the invention prevent of mixing of the source and reactant precursors and the particle generation.

In addition, an atomic layer deposition apparatus and method according to an embodiment of the invention provide selective deposition of the atomic layers on the selected region of the substrate without using the shadow mask.

An apparatus for depositing atomic layers according to an embodiment of the invention injects source precursor to the whole surface of the substrate with the substrate or the showerhead moving forward and reactant precursor to the whole surface of the substrate with the substrate or the showerhead moving backward. The apparatus can prevent mixing of the source and reactant precursors as the source and reactant precursors are injected with the time interval.

An apparatus for depositing atomic layers according to an embodiment of the invention injects purge gas through the showerhead simultaneously when the source and reactant precursors are injected to the substrate. The apparatus exhausts the purge gas, the source precursor and the reactant precursor through the showerhead immediately after they are injected. The apparatus can provide a reduced cycle time.

An apparatus for depositing atomic layers according to an embodiment of the invention has a moving distance of the showerhead or the substrate as short as a pitch of injection units. For example, the pitch is between 30 mm to 100 mm. Therefore the apparatus can provide a greater throughput and a reduced footprint.

An apparatus for depositing atomic layers according to an embodiment of the invention may deposit the atomic layers selectively on a selected region of the substrate without using a shadow mask by controlling the moving distance of the showerhead or the substrate.

An apparatus for depositing atomic layers according to an embodiment of the invention comprises a showerhead disposed about the substrate and having an injection surface comprising a hole for injecting first materials, a hole for injecting second materials, a hole for injecting purge gas and a hole for exhaust, a moving mechanism configured to move the substrate support or the showerhead back and forth between first and second locations along a first direction, and a control mechanism to control supplies of the first materials injected through the hole for injecting the first materials, the second materials injected through the hole for injecting the second materials, the purge gas injected through the hole for injecting purge gas and the exhaust supplied to the substrate through the hole for exhaust. The control mechanism is configured not to supply the first and second materials to the substrate at the same time and further configured to supply the purge gas and the exhaust to the substrate while the first and second materials are supplied to the substrate through the respective holes for injecting the first and second materials.

An apparatus for depositing atomic layers according to an embodiment of the invention is configured such that the injection surface comprises at least one injection unit which is disposed along the first direction and extends to a direction perpendicular to the first direction. Each of the injection unit of the apparatus comprises a hole array for injecting the first materials, a hole array for injecting the second materials and at least one hole array for the exhaust.

An apparatus for depositing atomic layers according to an embodiment of the invention is configured such that the at least one hole array for the exhaust comprises first and second hole arrays for the exhaust. The apparatus is further configured such that the hole array for injecting the first materials is disposed between the first and second hole arrays for the exhaust and the hole array for injecting the second materials is disposed between the hole array for injecting the first materials and the second hole array for the exhaust.

An apparatus for depositing atomic layers according to an embodiment of the invention is configured such that the first and second materials are exhausted through the first and second hole arrays for the exhaust, respectively.

An apparatus for depositing atomic layers according to an embodiment of the invention is configured such that the injection unit comprises a first hole array for injecting the purge gas which is disposed between the hole arrays for injecting the first and second materials.

An apparatus for depositing atomic layers according to an embodiment of the invention is configured such that a third hole array for the exhaust is disposed between the hole array for injecting the first materials and the first hole array for injecting the purge gas. The apparatus is further configured such that a fourth hole array for the exhaust is disposed between the hole array for injecting the second materials and the first hole array for injecting the purge gas.

An apparatus for depositing atomic layers according to an embodiment of the invention is configured such that a first hole array for injecting the purge gas is disposed between the hole array for injecting the first materials and the first hole array for the exhaust, a second hole array for injecting the purge gas is disposed between the hole array for injecting the first materials and the third hole array for the exhaust, a third hole array for injecting the purge gas is disposed between the hole array for injecting the second materials and a fourth hole array for the exhaust, and a fourth hole array for injecting the purge gas is disposed between the hole array for injecting the second materials and the second hole array for the exhaust.

An apparatus for depositing atomic layers according to an embodiment of the invention is configured such that the first materials is exhausted through the first and third hole arrays for the exhaust and the second materials is exhausted through the second and fourth hole arrays for the exhaust.

An apparatus for depositing atomic layers according to an embodiment of the invention is configured such that a hole array for injecting the purge gas is disposed between the at least one injection units.

An apparatus for depositing atomic layers according to an embodiment of the invention may be configured such that the injection surface comprises a purge gas injection surface extending from an end of the injection surface to the opposite end of the injection surface along the first direction. The purge gas injection surface of the apparatus does not comprise holes for injecting the first and second materials. The purge gas injection surface may comprise a hole for injecting the purge gas. The purge gas injection surface may comprise a hole for the exhaust. The purge gas injection surface may not comprise any holes for the purge gas and the exhaust. The apparatus does not deposit atomic layers on a surface of the substrate corresponding to the purge gas injection surface.

An apparatus for depositing atomic layers according to an embodiment of the invention is configured such that both ends of the injection surface have arc shapes in case that the substrate is circular.

An apparatus for depositing atomic layers according to an embodiment of the invention is configured such that the moving mechanism comprises a guide block coupled to the showerhead and a track coupled to a showerhead support configured to support the showerhead. The guide block is slidibly coupled to the track such that the showerhead moves back and forth on the track.

An apparatus for depositing atomic layers according to an embodiment of the invention is configured such that the moving mechanism comprises a rotator of a linear motor coupled to the showerhead and a stator of the linear motor coupled to the showerhead support.

An apparatus for depositing atomic layers according to an embodiment of the invention comprises a hole for injecting clean or inert gas towards the showerhead and the substrate support. The hole is disposed under the showerhead support.

An apparatus for depositing atomic layers according to an embodiment of the invention comprises a first chamber coupled to the showerhead support and configured to approach to the showerhead and the substrate support through an opening of the first chamber such that the first chamber surrounds the showerhead and the showerhead support.

An apparatus for depositing atomic layers according to an embodiment of the invention comprises a hole for exhaust, which is disposed about the substrate support and a side wall of the first chamber.

An apparatus for depositing atomic layers according to an embodiment of the invention comprises a second chamber which is configured to isolate the showerhead support, the showerhead, the substrate support and the hole for exhaust from the environment.

An apparatus for depositing atomic layers according to an embodiment of the invention comprises a first frame, a second frame, shafts whose one ends are coupled to the first frame and other ends are coupled to the second frame, a showerhead support movably coupled to the shafts, and a moving mechanism configured to move the showerhead support between the first and second frames.

An apparatus for depositing atomic layers according to an embodiment of the invention is configured such that the at least one injection units are disposed at the same interval X along the first direction. The apparatus is further configured such that the hole array for injecting the first materials of the at least one injection units is disposed a certain distance X1 away from the hole array for injecting the second materials of the at least one injection unit.

An apparatus for depositing atomic layers according to an embodiment of the invention is configured such that the at least one injection unit comprises a first injection unit disposed at a first end of the injection surface and a second injection unit disposed at an opposite end of the first end of the injection surface. The apparatus is further configured such that, when the showerhead is located at the first location, a first end of the substrate placed on the substrate support is located between a hole array 80b of the first injection unit for injecting the second materials and a hole array 80a of a third injection unit, which is disposed next to the first injection unit, for injecting the first materials, and a second end of the substrate which is opposite to the first end of the substrate is located between a hole array 80b of the second injection unit for injecting the second materials and a location which is X-X1 distance away along the first direction from the hole array 80b of the second injection unit for injecting the second materials. The first end of the substrate may be aligned to the hole array 80b of the first injection unit for injecting the second materials, and the second end of the substrate may be aligned to a location X-X1 distance away along the first direction from the hole array 80b of the second injection unit for injecting the second materials.

The apparatus is further configured such that, when the showerhead is located at the second location, the first end of the substrate is located between the hole array 80a of the first injection unit for injecting the first materials and a location which is X-X1 distance away along a reverse direction of the first direction from the hole array 80a of the first injection unit for injecting the first materials, and the second end of the substrate is located between the hole array 80a of the second injection unit for injecting the first materials and the hole array 80b of a fourth injection unit, which is disposed next to the second injection unit, for injecting the second materials. The first end of the substrate may be aligned to a location which is X-X1 distance away along the reverse direction of the first direction from the hole array 80a of the first injection unit for injecting the first materials, and the second end of the substrate may be aligned to the hole array 80a of the second injection unit for injecting the first materials.

An apparatus for depositing atomic layers according to an embodiment of the invention is configured such that the at least one injection units comprise a first injection unit disposed at a first end of the injection surface and a second injection unit disposed at an opposite end of the first end. The apparatus is further configured such that the showerhead further comprises an injection unit for injecting the first materials, which is disposed next to the second injection unit. The apparatus is also configured such that the injection unit for injecting the first materials comprises a hole array for injecting the first materials and hole arrays for the exhaust. The hole array for injecting the first materials is disposed at a location which is a certain distance X away from the hole array 80a of the second injection unit for injecting the first materials. The hole arrays for the exhaust are disposed before and after the hole array for injecting the first materials.

An apparatus for depositing atomic layers according to an embodiment of the invention is configured such that, when the showerhead is located at the first location, the first end of the substrate placed on the substrate support is located between the hole array 80b of the first injection unit for injecting the second materials and a hole array 80a of a third injection unit, which is disposed next to the first injection unit, for injecting the first materials, and the second end of the substrate which is opposite to the first end of the substrate is located between a hole array 80a of the first injection unit for injecting the first materials and a location which is X1 distance away along the first direction from the hole array 80a of the first injection unit for injecting the first materials. The first end of the substrate may be aligned to the hole array 80b of the first injection unit for injecting the second materials and the second end of the substrate may be aligned to a location which is X1 distance away along the first direction from the hole array 80a of the first injection unit for injecting the first materials.

The apparatus is further configured such that, when the showerhead is located at the second location, the first end of the substrate is located between the hole array 80a of the first injection unit for injecting the first materials and a location which is X-X1 distance away along the reverse direction of the first direction from the hole array 80a of the first injection unit for injecting the first materials, and the second end of the substrate is located between the hole array 80a of the second injection unit for injecting the first materials and the hole array 80b of the second injection unit for injecting the second materials. The first end of the substrate may be aligned to a location which is X-X1 distance away along the reverse direction of the first direction from the hole array 80a of the first injection unit for injecting the first materials, and the second end of the substrate may be aligned to the hole array 80b of the second injection unit for injecting the second materials.

An apparatus for depositing atomic layers according to an embodiment of the invention is configured such that the moving mechanism can pivot the showerhead between first and second angular locations about a first axis instead of moving the showerhead back and forth linearly.

An apparatus for depositing atomic layers according to an embodiment of the invention is configured such that the showerhead which can be pivoted about the first axis by the moving mechanism comprises a single injection unit.

An apparatus for depositing atomic layers according to an embodiment of the invention is configured such that the moving mechanism pivots the showerhead between the first and second angular locations about the first axis and the first and second angular axes correspond to the first and second locations respectively.

A method for depositing atomic layers according to an embodiment of the invention comprises a disposing step to dispose a substrate on a substrate support; a disposing step to dispose about the substrate a showerhead having an injection surface which comprises a hole for injecting first materials, a hole for injecting second materials which reacts with the first materials to form an atomic layer, a hole for injecting purge gas and a hole for exhaust pump; a first moving step to move the substrate support or the showerhead from a first location to a second location along a first direction; an injecting and exhausting step to inject the first materials and the purge gas to the substrate through the hole for injecting the first materials and the hole for injecting the purge gas respectively and to exhaust the first materials and the purge gas through the hole for exhaust during the first moving step; a second moving step to move the substrate support or the showerhead from the second location to the first location along a reverse direction of the first direction; and an injecting and exhausting step to inject the second materials and the purge gas to the substrate through the hole for injecting the second materials and the hole for injecting the purge gas respectively and to exhaust the second materials and the purge gas through the hole for exhaust during the second moving step. The method does not inject the first and second materials during the second and first moving steps, respectively.

A method for depositing atomic layers according to an embodiment of the invention uses the injection surface which comprises at least one injection unit that is disposed along the first direction and extends to a direction perpendicular to the first direction. The method uses the injection unit, each of which comprises a hole array for injecting the first materials, a hole array for injecting the second materials, a hole array for injecting the purge gas and at least one hole array for exhaust.

A method for depositing atomic layers according to an embodiment of the invention does not inject the first and second materials while the showerhead is moving from the first location to a third location during the first moving step. The method does not inject the second materials but inject the first materials while the showerhead is moving from the third location to the second location.

A method for depositing atomic layers according to an embodiment of the invention has the third location between the first and second locations, which is closer to or coincides with the first location.

A method for depositing atomic layers according to an embodiment of the invention does not inject the first and second materials while the showerhead is moving from the second location to a fourth location during the second moving step. The method does not inject the first materials but inject the second materials while the showerhead is moving from the fourth location to the first location.

A method for depositing atomic layers according to an embodiment of the invention has the fourth location between the first and second locations, which is closer to or coincides with the second location.

A method for depositing atomic according to an embodiment of the invention may use different moving speeds of the showerhead during the first and second moving steps. For example, the method may use the greater moving speed during the first moving step than during the second moving step.

A method for depositing atomic layers according to an embodiment of the invention further comprises a first purge step after the first moving step is completed and before the second moving step begins. During the first purge step the method does not inject the first and second materials but injects and exhausts the purge gas.

A method for depositing atomic layers according to an embodiment of the invention further comprises a second purge step after the second moving step is completed and before the first moving step begins. During the second purge step the method does not inject the first and second materials but injects and exhausts the purge gas.

A method for depositing atomic layers according to an embodiment of the invention may use different times to purge during the first and second purge steps.

A method for depositing atomic layers according to an embodiment of the invention uses a distance, which is similar to the distance between holes for injecting the first materials of the adjacent injection units, as a distance between the first and second locations.

A method for depositing atomic layers according to an embodiment of the invention uses a distance, which is smaller than the distance between the holes for injecting the first materials of the adjacent injection units, as the distance between the first and second locations. The method does not deposit atomic layers on the whole surface of the substrate but on a specific.

A method for depositing atomic layers according to an embodiment of the invention exhausts the first and second materials through first and second holes of the at least one holes for exhaust, respectively.

A method for depositing atomic layers according to an embodiment of the invention injects the purge gas through the hole for injecting the second materials during the first moving step and injects the purge gas through the hole for injecting the first materials during the second moving step.

A method for depositing atomic layers according to an embodiment of the invention, a method comprises the disposing step to dispose the substrate on the substrate support; the disposing step to dispose about the substrate the showerhead having the injection surface comprising the hole for injecting first materials, the hole for injecting the second materials which reacts with the first materials to form the atomic layer, the hole for injecting the purge gas and the hole for exhaust; the first moving step to move the substrate support or the showerhead from the first location to the second location along the first direction; the injecting and exhausting step to inject the first materials and the purge gas to the substrate through the hole for injecting the first materials and the hole for injecting the purge gas respectively and to exhaust the first materials and the purge gas through the hole for exhaust during the first moving step; the second moving step to move the substrate support or the showerhead from the second location to the first location along the reverse direction of the first direction; an injecting and exhausting step to inject and exhaust the purge gas during the second moving step; a third moving step to move the substrate support or the showerhead from the first location to the second location along the first direction; and an injecting and exhausting step to inject the second materials and the purge gas to the substrate through the hole for injecting the second materials and the hole for injecting the purge gas respectively and to exhaust the second materials and the purge gas through the hole for exhaust during the third moving step. The method does not inject the second materials during the first and second moving steps and the first materials during the second and third moving steps.

A method for depositing atomic layers according to an embodiment of the invention uses the injection surface which comprise the at least one injection unit that is disposed along the first direction and extends to the direction perpendicular to the first direction. The method uses the injection unit, each of which comprises the hole array for injecting the first materials, the hole array for injecting the second materials, the hole array for injecting the purge gas and the at least one hole array for exhaust.

A method for depositing atomic according to an embodiment of the invention may use different moving speeds of the showerhead during the first, second and third moving steps.

A method for depositing atomic layers according to an embodiment of the invention uses the distance, which is similar to the distance between the holes for injecting the first materials of the adjacent injection units as the distance between the first and second locations.

A method for depositing atomic layers according to an embodiment of the invention uses the distance, which is smaller than the distance between the holes for injecting the first materials of the adjacent injection units, as the distance between the first and second locations. The method does not deposit atomic layers on the whole surface of the substrate but on a specific region of the substrate.

A method for depositing atomic layers according to an embodiment of the invention exhausts the first and second materials through the first and second holes of the at least one holes for exhaust, respectively.

A method for depositing atomic layers according to an embodiment of the invention injects the purge gas through the hole for injecting the second materials during the first moving step and injects the purge gas through the hole for injecting the first materials during the third moving step.

A method for depositing atomic layers according to an embodiment of the invention exhausts the purge gas through the hole for exhaust during the second moving step.

A method for depositing atomic layers according to an embodiment of the invention injects the purge gas through the holes for injecting the first and second materials during the second moving step.

Other aspects and advantages of the present invention will become apparent from the following detailed description, taken in conjunction with the accompanying drawings, illustrated by way of example of the principles of the invention.

### ADVANTAGE OF THE INVENTION

According to the invention, the apparatus and the method provide a reduced cycle time, a short reciprocating distance of the substrate or the showerhead, and a reduced footprint of the apparatus. According to the invention the source and reactant precursors are not mixed and therefore particle generation is controlled. According to the invention, the apparatus and the method provide selective atomic layer deposition on a selected region of the substrate without the shadow mask.

According to the invention, the apparatus and the method provide selective deposition of the atomic layers on the selected region of the substrate without using the shadow mask.

### BRIEF DESCRIPTION OF THE DRAWINGS

FIG. 1 is a side view of an atomic layer deposition apparatus according to a conventional technology.

FIG. 2 is a top view of the atomic layer deposition apparatus according to the conventional technology.

FIG. 3 is a side view of an atomic layer deposition apparatus according to an embodiment of an invention.

FIG. 4 is a front view of the atomic layer deposition apparatus according to an embodiment of the invention.

FIG. 5 is a front view of the atomic layer deposition apparatus according to an embodiment of the invention.

FIG. 6 is a front view of the atomic layer deposition apparatus according to an embodiment of the invention.

FIG. 7 is a front view of the atomic layer deposition apparatus according to an embodiment of the invention.

FIG. 8 is a bottom view of a showerhead according to an embodiment of the invention.

FIG. 9 is a cross sectional view of the showerhead illustrated in FIG. 8.

FIG. 10 is a cross sectional view of the showerhead illustrated in FIG. 8.

FIG. 11 is a bottom view of the showerhead according to an embodiment of the invention.

FIG. 12 is a bottom view of an injection unit according to an embodiment of the invention.

FIG. 13 is a bottom view of the showerhead according to an embodiment of the invention.

FIG. 14 is a bottom view of the injection unit according to an embodiment of the invention.

FIG. 15 is a top view of the substrate support according to an embodiment of the invention.

FIG. 16 is a top view of the substrate support and the showerhead according to an embodiment of the invention.

FIG. 17 is a three dimensional view of a protecting chamber according to an embodiment of the invention.

FIG. 18 is a cross sectional view of the atomic layer deposition apparatus according to an embodiment of the invention.

FIG. 19 is a bottom view of the showerhead according to an embodiment of the invention.

FIG. 20 is a top of the atomic layer deposition apparatus according to an embodiment of the invention.

FIG. 21 is a cross sectional view of the atomic layer deposition apparatus according to an embodiment of the invention.

FIG. 22 is a bottom view of the showerhead according to an embodiment of the invention.

FIG. 23 is a bottom view of the showerhead according to an embodiment of the invention.

FIG. 24 is a top view of the substrate comprising the atomic layers deposited by an embodiment of the invention.

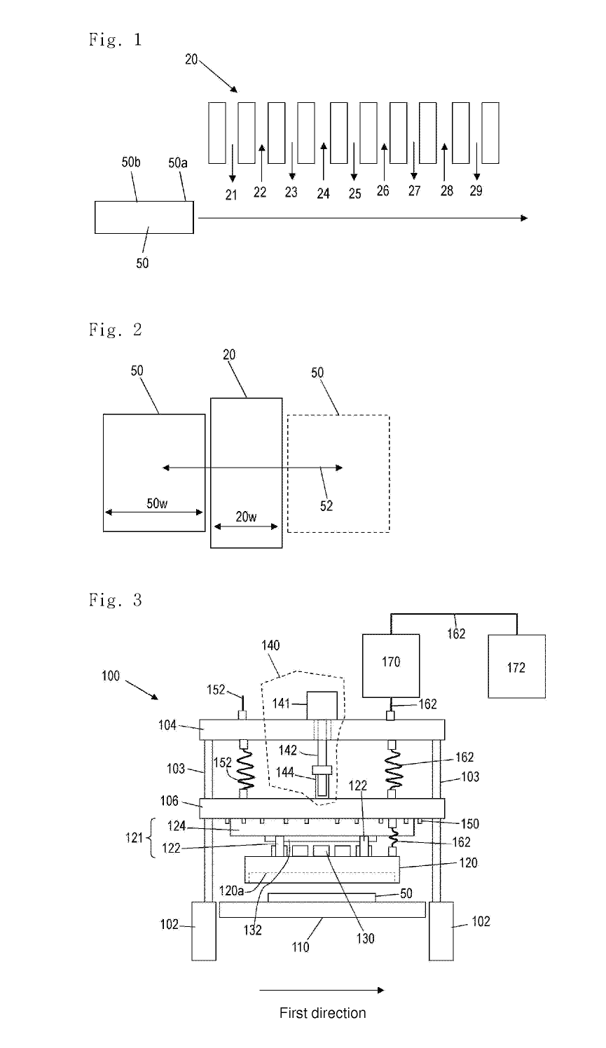

### DETAILED DESCRIPTION

With reference to the figures attached, embodiments according to the invention are described.

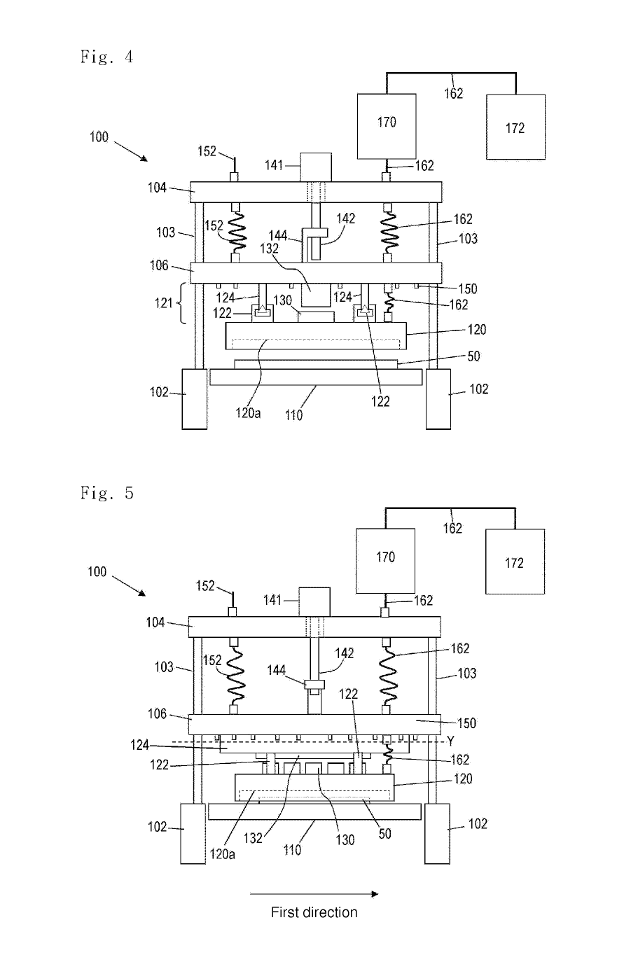

FIGS. 3 and 4 are side and front views of an atomic layer deposition apparatus according to an embodiment of the invention. Referring to FIGS. 3 and 4, the ALD apparatus 100 may comprise a lower frame 102, an upper frame 104, shafts 103, a substrate support 110, a showerhead support 106, a showerhead 120, a showerhead reciprocating mechanism 121, a showerhead vertical moving mechanism 140 and a gas supply control system 170. To heat the substrate support 100 the ALD 100 may comprise a heating element not illustrated) such as a lamp heater disposed below the substrate support 110 or a heating wire embedded in the substrate support 110.

One ends of the shafts 103 are coupled to the lower frame 102 and the opposite ends are coupled to the upper frame 104. The showerhead support 106 is coupled to the shafts 103 such that it moves vertically between the upper frame 104 and the substrate support 110.

The showerhead 120 is supported by the showerhead support 106 by being coupled to an overhead track 124 by guide blocks 122. One ends of the guide blocks 122 are coupled to a top surface of the showerhead 120 and the opposite ends are movably coupled to the overhead track 124, which is coupled to a bottom surface of the showerhead support 106. The guide blocks 122 and the overhead track 124 are elements of the showerhead reciprocating mechanism 121. A non-contact type magnetic levitation track can be used instead of the overhead track 124 and the guide block 122.

A linear motor can be comprised as another element of the showerhead reciprocating mechanism 121. The linear motor consists of a rotator 130 and a stator 132. The stator 132 is coupled to the bottom surface of the showerhead support 106 such that its has the same direction with the overhead track 124. The rotator 130 is coupled to the top surface of the showerhead 120 such that it faces the stator 132. A permanent magnet can be used as the rotator 130 and an electrical coil connected to a source of electricity can be used as the stator 132. The showerhead 120 connected to the stator 130 can be moved back and forth between first and second positions along a first direction by applying attractive or repulsive force to the rotator 130 by electromagnetic force induced when the electricity flows along the coil. The first direction is the direction parallel to the substrate 50 or the substrate support 110.

The showerhead vertical moving mechanism 140 comprises a servo motor 141 coupled to the upper frame 104, a screw 142 rotated by the servo motor 141, and a female screw 144 whose one end is coupled to the top surface of the showerhead support 106 and other end is movably coupled to the screw 142. The showerhead support 106 and therefore the showerhead 120 supported by the showerhead support 106 can be moved vertically by rotating the screw 142 by the servo motor 141.

The vertical location of the showerhead 120 illustrated in FIGS. 3 and 4 is the location for loading and unloading the substrate 50. At the loading and unloading location, a substrate transporter not illustrated can transfer the substrate with the substrate support 110 as the substrate 50 is exposed from showerhead 120.

FIG. 5 is a side view of the ALD apparatus 100 after the showerhead 120 is moved down to a deposition location. At the deposition location the showerhead 120 approaches to the substrate support 110 and the substrate 50 and surrounds the substrate 50. When the showerhead 120 is located at the deposition location, an injection surface 120a of the showerhead 120 may be positioned 0.2˜3 mm apart from the surface of the substrate. According to an embodiment, the injection surface 120a may be located 0.1˜30 mm apart from the substrate. The distance between the injection surface 120a and the substrate at the deposition location may be adjusted by the showerhead vertical moving mechanism 140.

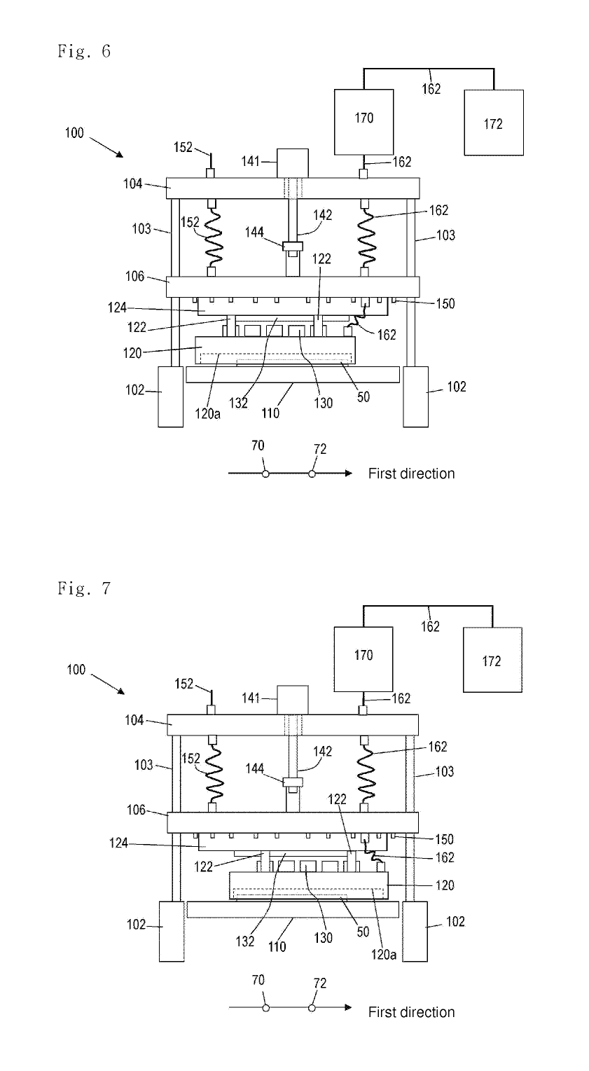

The ALD apparatus 100 when the showerhead 120 is located at first and second locations 70 and 72 is illustrated in FIGS. 6 and 7, respectively. FIGS. 6 and 7 are side views of the ALD apparatus 100 when the showerhead 120 is located at the first and second locations 70 and 72 respectively. The first and second locations 70 and 72 are locations for depositing atomic layers.

The ALD 100 is configured to coat the substrate 50 with a first reaction layer by injecting source precursor and purge gas at the same time while the showerhead 120 is moved from the first location 70 to the second location 72. The ALD 100 is further configured to coat the first reaction layer with a second reaction layer by injecting reactant precursor and the purge gas at the same time while the showerhead 120 is moved from the second location 72 to the first location 70. The showerhead 120 deposits a desired thickness or a desired number of atomic layers by reciprocating repeatedly between the first and second locations 70 and 72 and coating the surface of the substrate 50 alternately with the first and second reaction layers. The ALD apparatus 100 may be configured such that the source and reactant precursors and the purge gas which were injected to the substrate 50 are exhausted in real time through the showerhead 120.

Turning back to FIGS. 3 and 4, gas injection holes 150 may be disposed at a lower part of the showerhead support 106. The gas injection holes 150 are connected to a source of inert gas such as nitrogen gas or a source of filtered-particle-free clean air. The gas injection holes 150 are configured to inject purge gas such as the inert gas or the clean air. The injected purge gas purges particles, which can be generated from the showerhead reciprocating mechanism 121 when the showerhead 120 moves back and forth, to outside of the ALD apparatus 100.

The gas supply control system 170 is configured to control supplies of the source precursor, the reactant precursor, the purge gas and the exhaust which are supplied to the showerhead 120 through respective supply conduits 162 from sources of the source precursor, the reactant precursor and the purge gas and an exhaust pump, respectively. The exhaust is used to exhaust the source precursor, the reactant precursor and the purge gas. It is noted that the gas supply control system 170 is configured not to supply the source and reactant precursors simultaneously. The gas supply control system 170 may be configured to supply the source precursor and the purge gas simultaneously, the reactant precursor and the purge gas simultaneously, or only the purge gas. The gas supply control system 170 may be configured to supply the exhaust to the showerhead 120 while the source and reactant precursors and the purge gas are supplied. Even though a single conduit 162 is illustrated in FIGS. 3 and 4, respective conduits are connected to the showerhead to supply the source precursor, the reactant precursor, the purge gas and the exhaust separately.

Flexible stainless steel hoses such as FM series of Swagelok Company may be used as the conduits for the source and reactant precursors. Alternately tubes consisting of a stainless steel liner wrapped by a heat conducing plastic materials may be used.

A conduit to supply cooling water to cool down the showerhead 120 may be embedded in the showerhead 120. The conduit to supply the cooling water is connected to a source of the cooling water not illustrated. The cooling water controls the temperature of the showerhead 120 by circulating the source of the cooling water and the showerhead 120.

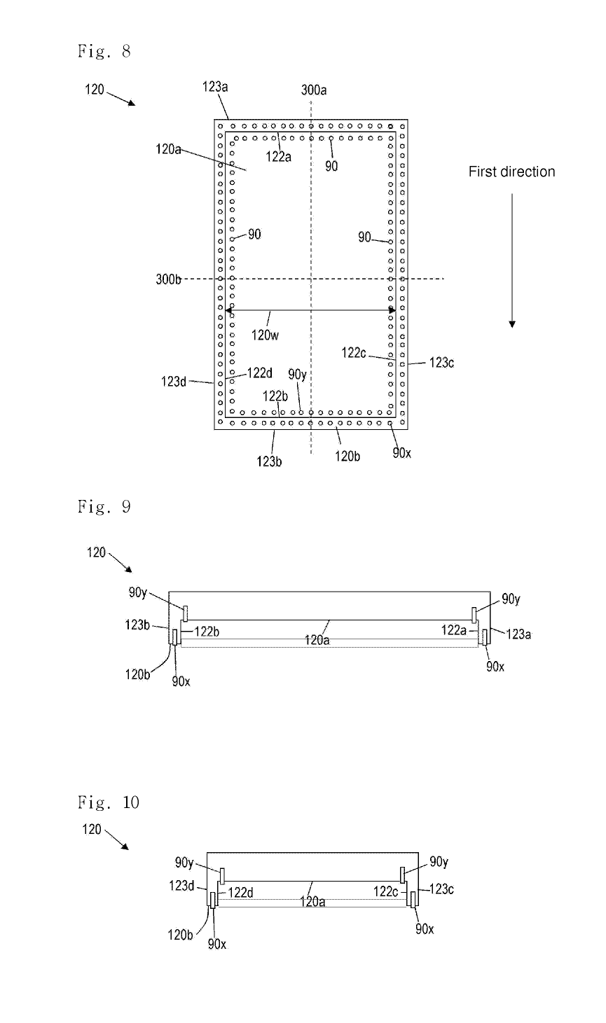

Referring to FIGS. 8, 9 and 10, the showerhead 120 is described. FIG. 8 is a bottom view of the showerhead 120 and FIGS. 9 and 10 are cross sections of 300a and 300b, respectively, illustrated in FIG. 8. The showerhead 120 comprises first, second, third and fourth inner surfaces 122a˜122d, first, second, third and fourth outer surfaces 123a˜123d, and a peripheral bottom surface 120b. The first, second, third and fourth inner surfaces 122a˜122d forms an inner sidewall of a chamber of the showerhead and the first, second, third and fourth outer surfaces 123a˜123d forms an outer sidewall of the showerhead 120. The peripheral bottom surface 120a is the surface extended from the injection surface 120a.

On the peripheral bottom surface 120b of the showerhead, holes 90X for injecting the purge gas can be disposed such that they surround the injection surface 120a. On the injection surface 120a adjacent to the first, second, third and fourth inner surfaces 122a˜122d holes 90y for injecting the purge gas can be disposed such that the holes 90y surround the injection surface 120a.

Referring to FIG. 11, the injection surface 120a of the showerhead 120 according to an embodiment of the invention is described. FIG. 11 is a bottom view of the showerhead 120. The showerhead 120 comprises n injection units on the injection surface 120a, which are SU(1), SU(2), . . . SU(n). The injection units extend along a direction perpendicular to the first direction. SU(1) and SU(n) are disposed at the both ends of the injection surface 120a respectively and the other injection units are disposed serially along the first direction between SU(1) and SU(n).

The injection units may be disposed at a constant interval X along the first direction. A width along the first direction of the injection unit may be, for example, between 30 mm and 200 mm. A hole array 90c for injecting the purge gas, which extends along the direction perpendicular to the first direction, may be disposed between the injection units.

Each of the injection units (SU) comprises first and second hole arrays 92a and 92b for exhaust, which extend along the perpendicular direction and are disposed before and after the respective injection unit. Between the hole arrays 92a and 92b for exhaust, hole arrays 80a and 80b for injecting the source and reactant precursors respectively are disposed such that they extend parallel to the hole arrays 92a and 92b.

The first and second hole arrays 92a and 92b for exhaust are connected to the source of exhaust pump. The respective exhaust may be controlled individually by the gas supply control system 170.

While the source precursor is injected through the hole array 80a but injection of the reactant precursor through the hole array 80b is stopped, for example, the first hole array 92a for exhaust, which is adjacent to the hole array 80a for injecting the source precursor, is open to the source of exhaust to exhaust the source precursor through the hole array 92a but the connection of the second hole array 92b, which is adjacent to the hole array 80b for injecting the reactant precursor, with the source of exhaust is cut off to stop exhaust through the hole array 92b. In a similar manner, while the reactant precursor is injected through the hole array 80b but injection of the source precursor through the hole array 80a is stopped, the second hole array 92b for exhaust, which is adjacent to the hole array 80b for injecting the reactant precursor, is open to the source of exhaust to exhaust the reactant precursor through the hole array 92b but the connection of the first hole array 92a, which is adjacent to the hole array 80a for injecting the source precursor, with the source of exhaust is cut off to stop exhaust through the hole array 92a. Therefore the first and second hole arrays 92a and 92b can be used to exhaust the source and reactant precursors, respectively.

Referring to FIG. 11, between the hole array 80a for injecting the source precursor and the hole array 80b for injecting the reactant precursor, a hole array 90t for injecting the purge gas may be disposed such that it extends parallel to the hole arrays 80a and 80b.

Between the hole array 80a for injecting the source precursor and the hole array 90t for injecting the purge gas, a third hole array 92c for exhaust may be disposed such that it extends parallel to the hole arrays 80a and 90t. Between the hole array 80b for injecting the reactant precursor and the hole array 90t for injecting the purge gas, a fourth hole array 92d for exhaust may be disposed such that it extends parallel to the hole arrays 80b and 90t.

The third and fourth hole arrays 90c and 90d for exhaust are connected to source of exhaust pump. The respective exhaust may be controlled individually by the gas supply control system 170.

While the source precursor is injected through the hole array 80a but injection of the reactant precursor through the hole array 80b is stopped, for example, the first and third hole arrays 92a and 92c for exhaust, which are adjacent to the hole array 80a for injecting the source precursor, are open to the source of exhaust to exhaust the source precursor through the hole arrays 92a and 92c but the connection of the second and fourth hole arrays 92b and 92d, which are adjacent to the hole array 80b for injecting the reactant precursor, with the source of exhaust is cut off to stop exhaust through the hole arrays 92b and 92d. In a similar manner, while the reactant precursor is injected through the hole array 80b but injection of the source precursor through the hole array 80a is stopped, the second and fourth hole arrays 92b and 92d for exhaust, which are adjacent to the hole array 80b for injecting the reactant precursor, are open to the source of exhaust to exhaust the reactant precursor through the hole arrays 92b and 92d but the connection of the first and third hole arrays 92a and 92c, which are adjacent to the hole array 80a for injecting the source precursor, with the source of exhaust is cut off to stop exhaust through the hole arrays 92a and 92c. Therefore the first and third hole arrays 92a and 92c and the second and fourth hole arrays 92b and 92d can be used to exhaust the source and reactant precursors, respectively.

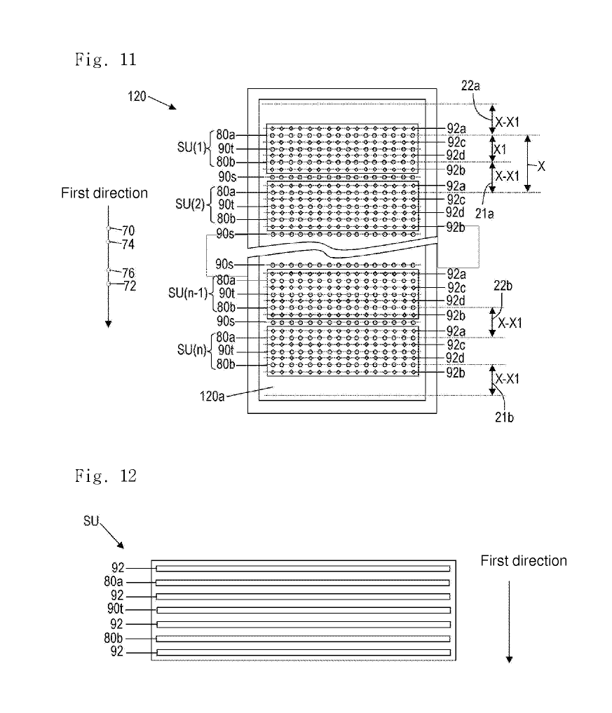

Even though each of the hole arrays 80a, 80b, 90s, 90t, 92 illustrated in FIG. 11 consists of the discrete holes, the holes may be connected to have a slit structure as illustrated in FIG. 12. FIG. 12 is a bottom view of the injection unit comprising the slit structure which can be used in the showerhead illustrated in FIG. 11.

Turning back to FIG. 11, the showerhead 120 is further described. When the showerhead 120 is located at the first location 70, a first end of the substrate 50, not illustrated in FIG. 11 is located at a location 21a, which is between a hole array 80b of the first injection unit SU(1) for injecting the reactant precursor and a hole array 80a of a second injection unit SU(2) for injecting the source precursor. A second end of the substrate is located at a location 21b, which is between a hole array 80b of the n'th injection unit SU(n) for injecting the reactant precursor and a location which is X-X1 distance away along the first direction from the hole array 80b of the n'th injection unit SU(n) for injecting the reactant precursor. The first end of the substrate may be aligned to the hole array 80b of the first injection unit SU(1) for injecting the reactant precursor, and the second end of the substrate may be aligned to the location which is X-X1 distance away along the first direction from the hole array 80b of the n'th injection unit SU(n) for injecting the reactant precursor.

When the showerhead 120 is located at the second location, the first end of the substrate is located at a location 22a, which is between the hole array 80a of the first injection unit SU(1) for injecting the source precursor and a location which is X-X1 distance away along the reverse direction of the first direction from the hole array 80a for injecting the source precursor. The second end of the substrate is located at a location 22b, which is between a hole array 80b of the (n−1)'th injection unit SU(n−1) for injecting the reactant precursor and the hole array 80a of the n'th injection unit SU(n) for injecting the source precursor.

The first end of the substrate may be aligned to the location which is X-X1 distance away along the reverse direction of the first direction from the hole array 80a of the first injection unit SU(1) for injecting the source precursor, and the second end of the substrate may be aligned to the hole array 80a of the n'th injection unit SU(n) for injecting the source precursor and the second end of the substrate.

Referring to FIG. 13, a showerhead 420 according to an embodiment according of the invention is described, FIG. 13 is a bottom view of the showerhead 420. The showerhead 420 further comprises an injection unit SU(n+1) for injecting the source precursor. The added injection unit SU(n+1) is disposed on an end of the showerhead 420 such that it is adjacent to the n'th injection unit SU(n). The injection unit SU(n+1) comprises a hole array 80a for injecting the source precursor, which extends to the direction perpendicular to the first direction. The injection unit SU(n+1) may further comprise hole arrays 92a and 92b for exhaust, which are disposed before and after the hole array 80a, respectively. The hole array 80a for injecting the source precursor of the injection unit SU(n+1) may be disposed at a location which is a certain distance X away from the hole array 80a of the n'th injection unit SU(n).

When the showerhead 420 is located at the first location, the first end of the substrate 50 not illustrated in FIG. 13 is located at a location 21a, which is between the hole array 80b of the first injection unit SU(1) and the hole array 80a of the second injection unit SU(2). The second end of the substrate is located at a location 23b, which is between the hole array 80a of the n+1'th injection unit SU(n+1) and a location which is X1 distance away along the first direction from the hole array 80a of the n+1'th injection unit SU(n+1). The first end of the substrate may be aligned to the hole array 80b of the first injection unit SU(1), and the second end may be aligned to the location which is X1 distance away along the first direction from the hole array 80a of the n+1'th injection unit SU(n+1).

When the showerhead 420 is located at the second location, the first end of the substrate is located at a location 22a, which is between the hole array 80a of the first injection unit SU(1) and a location which is X-X1 distance away along the reverse direction of the first direction from the hole array 80a of the first injection unit SU(1). The second end of the substrate is located at a location 24b, which is between the hole array 80a of the n'th injection unit SU(n) and the hole array 80b of the n'th injection unit SU(n). The first end of the substrate may be aligned to a location which is X-X1 distance away along the reverse direction of the first direction from the hole array 80a of the first injection unit SU(1), and the second end of the substrate may be aligned to the hole array 80b of the n'th injection unit SU(n).

Turning back to FIG. 11, a method for depositing atomic layers with the showerhead 120 according to an embodiment of the invention comprises the following steps. A method for depositing atomic layers with the showerhead 420 comprises the same steps.

(1) a first moving step wherein the showerhead 120 is moved from the first location 70 to the second location 72,

(2) a source precursor injection step during the first moving step wherein the source precursor is injected to the substrate 50 through the hole array 80a of the injection units (SU) but supply of the reactant precursor through the hole array 80b is cut off,

(3) a purge step during the first moving step wherein the purge gas is injected to the substrate 50 through the at least one hole arrays 90s and 90t,

(4) an exhaust step during the first moving step wherein the source precursor and the purge gas are exhausted through one of the at least one hole arrays 92a-92d for exhaust of the injection unit SU,

(5) a second moving step wherein the showerhead 120 is moved back from the second location 72 to the first location 70 along the reverse direction of the first direction,

(6) a reactant precursor injection step during the second moving step wherein the reactant precursor is injected to the substrate 50 through the hole arrays 80b of the injection units (SU) but supply of the source precursor through the hole array 80a is cut off,

(7) a purge step during the second moving step wherein the purge gas is injected to the substrate 50 through the at least one hole arrays 90s and 90t, and

(8) an exhaust step during the second moving step wherein the reactant precursor and the purge gas are exhausted through one of the at least one hole arrays 92a-92d for exhaust of the injection unit SU,

According to an embodiment of the invention, moving speeds of the showerhead 120 at the first and second moving steps may be different. For example, the speed at the first moving step is greater than the speed at the second moving step. Injection times of the source and reactant precursors can be controlled individually by using the different moving speeds.

According to an embodiment of the invention, a first purge step can be added after the first moving step is completed and before the second moving step begins. During the first purge step, the source and reactant precursors are not injected and only the purge gas is injected and exhausted.

According to an embodiment of the invention, a second purge step can be added after the second moving step is completed and before the first moving step begins. During the second purge step, the source and reactant precursors are not injected and only the purge gas is injected and exhausted.

Purge times at the first and second purge steps can be controlled individually. It is possible to purge longer time for the precursor which is not purged well out of the source and reactant precursors.

According to an embodiment of the invention, the purge gas can be injected during the first moving step through the hole array 80b for injecting the reactant precursor.

According to an embodiment of the invention, during the first moving step, the source precursor and the purge gas are exhausted by connecting at least one of the first and third hole arrays 92a and 92c for exhaust to the source of exhaust. The second and fourth hole arrays 92b and 92d are, however, cut off from the source of exhaust. According to the embodiment, the first and third arrays 92a and 92c are used to exhaust the source precursor and the second and fourth exhausts 92b and 92d are not used to exhaust the source precursor.

According to an embodiment of the invention, the purge gas can be injected during the second moving step through the hole array 80b for injecting the reactant precursor.

According to an embodiment of the invention, during the second moving step, the reactant precursor and the purge gas are exhausted by connecting at least one of the second and fourth hole arrays 92b and 92d to the source of exhaust. The first and third hole arrays 92a and 92c are, however, cut off from the source of exhaust. According to the embodiment, the second and fourth hole arrays 92b and 92d are used to exhaust the reactant precursor and the first and third exhausts 92a and 92c are not used to exhaust the reactant precursor.

According to an embodiment of the invention, a moving distance of the showerhead between the first and second locations 70 and 72 at the first and second moving steps is similar to the distance X between neighboring hole arrays 80a for injecting the source precursor or the pitch X of the injection units SU. It is possible to inject the source and reactant precursors and the purge gas by moving the showerhead at the distance of the distance X or the pitch X. According to the embodiment, atomic layers are deposited on the whole surface of the substrate.

According to an embodiment of the invention, atomic layers can be deposited on a specific region of the substrate instead of the whole surface of the substrate by injecting the source and reactant precursors selectively on the specific region of the substrate. In case of depositing atomic layers on the specific region, the source precursor injection step (2) which is the second step of the embodiment described above is replaced with the following step (2-1).

Referring to FIG. 11, the step (2-1) is described as below.

(2-1) a source precursor injection step wherein supplies of the source and reactant precursors through the respective hole arrays 80a and 80b of the injection units (SU) are cut off while the showerhead 120 is moved from the first location 70 to the third location 74, and the source precursor is injected through the hole array 80a but the supply of the reactant precursor through the hole array 80b is still cut off while the showerhead 120 is moved from the third location 74 to the second location 72.

The third location 74 is disposed between the first and second locations 70 and 72 such that it is closer to the first location 70. The third location 74 may coincide with the first location 70.

In case of depositing atomic layers on the specific region, the reactant precursor injection step (6) which is the sixth step of the embodiment described above is replaced with the following step (6-1).

(6-1) a reactant precursor injection step wherein supplies of the source and reactant precursors through the respective hole arrays 80a and 80b of the injection units (SU) are cut off while the showerhead 120 is moved from the second location 72 to the fourth location 74, and the reactant precursor is injected through the hole array 80b but the supply of the source precursor through the hole array 80a is still cut off while the showerhead 120 is moved from the fourth location 76 to the first location 70.

The fourth location 76 is disposed between the first and second locations 70 and 72 such that it is closer to the second location 72. The fourth location may coincide with the second location 72.

In the embodiment of the invention, it is possible to inject the source and reactant precursors on a part of the substrate instead of the whole surface of the substrate by making the moving distance of the showerhead 120, that is the distance between the first and second locations 70 and 72, smaller than the distance X between the neighboring hole arrays 80a or the pitch X of the injection units SU. Atomic layers are deposited only on the part of the substrate which is exposed to both of the source and reactant precursors.

In the embodiment of the invention, it is possible to inject the source and reactant precursors on the part of the substrate instead of the whole surface of the substrate by making the distance between the third and fourth locations 74 and 76 smaller than the distance X between the neighboring hole arrays 80a or the pitch X of the injection units SU.

A method of depositing the atomic layers by using the showerhead 120 according to an embodiment of the invention comprises the following steps.

(1) the first moving step wherein the showerhead 120 is moved from the first location 70 to the second location 72,

(2) the source precursor injection step during the first moving step wherein the source precursor is injected to the substrate 50 through the hole array 80a of the injection units (SU) but the supply of the reactant precursor through the hole array 80b is cut off,

(3) the purge step during the first moving step wherein the purge gas is injected to the substrate 50 through the at least one hole arrays 90s and 90t,

(4) the exhaust step during the first moving step wherein the source precursor and the purge gas are exhausted through at least one of the hole arrays 92a-92d for exhaust of the injection unit SU,

(5) the second moving step wherein the showerhead 120 is moved back from the second location 72 to the first location 70 along the reverse direction of the first direction,

(6) a purge step during the second moving step wherein the supplies of the source and reactant precursors through the respective hole arrays 80a and 80b of the injection units (SU) are cut off but the purge gas is injected through the at least of the hole arrays 90s and 90t for injecting the purge gas,

(7) an exhaust step during the second moving step wherein the purge gas is exhausted through the at least one hole arrays 92a-92d of the injection unit SU,

(8) a third moving step wherein the showerhead 120 is moved from the first location 70 to the second location 72,

(9) a reactant precursor injection step during the third moving step wherein the reactant precursor is injected to the substrate 50 through the hole array 80b of the injection units (SU) but the supply of the source precursor through the hole arrays 80a is cut off,

(10) a purge step during the third moving step wherein the purge gas is injected to the substrate 50 through the at least one hole arrays 90s and 90t, and

(11) an exhaust step during the third moving step wherein the reactant precursor and the purge gas are exhausted through the at least one hole arrays 92a-92d for exhaust of the injection unit SU.

According to an embodiment of the invention, the purge gas can be injected during the first moving step through the hole array 80b for injecting the reactant materials.

According to an embodiment of the invention, during the first moving step, the source precursor and the purge gas are exhausted by connecting at least one of the first and third hole arrays 92a and 92c for exhaust to the source of exhaust. The second and fourth hole arrays 92b and 92d are, however, cut off from the source of exhaust. According to the embodiment, the first and third arrays 92a and 92c are used to exhaust the source precursor and the second and fourth exhausts 92b and 92d are not used to exhaust the source precursor.

According to an embodiment of the invention, the purge gas can be injected during the third moving step through the hole array 80b for injecting the reactant materials.

According to an embodiment of the invention, during the third moving step, the reactant precursor and the purge gas are exhausted by connecting at least one of the second and fourth hole arrays 92b and 92d to the source of exhaust. The first and third hole arrays 92a and 92c are, however, cut off from the source of exhaust. According to the embodiment, the second and fourth hole arrays 92b and 92d are used to exhaust the reactant precursor and the first and third exhausts 92a and 92c are not used to exhaust the reactant precursor.

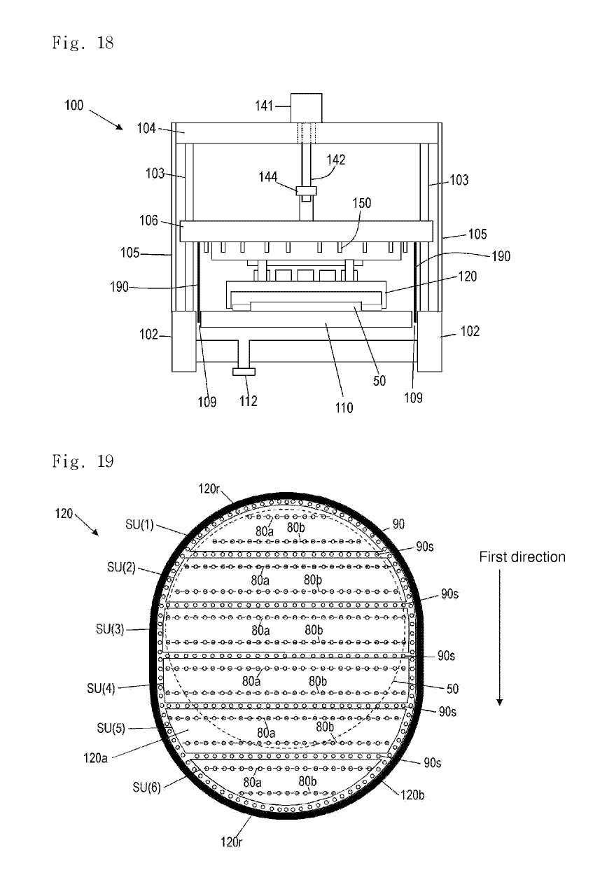

According to an embodiment of the invention, during the second moving step, the hole arrays 92a-92d for exhaust are cut off from the source of exhaust. In the embodiment, the purge gas injected from the hole arrays 90s and 90t may be exhausted through the hole for exhaust 112a of FIG. 15 disposed on the substrate support 110 or through the hole for exhaust 109 of FIG. 18 disposed about the substrate support.

According to an embodiment of the invention, the purge gas can be injected during the second moving step through the hole arrays 80a and 80b.

According to an embodiment of the invention, moving speeds of the showerhead 120 at the first, second and third moving steps may be different.

According to an embodiment of the invention, the moving distance of the showerhead between the first and second locations 70 and 72 at the first, second and third moving steps is similar to the distance X between neighboring hole arrays 80a for injecting the source precursor or the pitch X of the injection units SU. It is possible to inject the source and reactant precursors and the purge gas to the whole surface of the substrate by moving the showerhead at the distance of the distance X or the pitch X. According to the embodiment, atomic layers are deposited on the whole surface of the substrate.

In the embodiment of the invention, it is possible to inject the source and reactant precursors on the part of the substrate instead of the whole surface of the substrate by making the moving distance of the showerhead 120, that is the distance between the first and second locations 70 and 72, smaller than the distance X between the neighboring hole arrays 80a or the pitch X of the injection units SU.

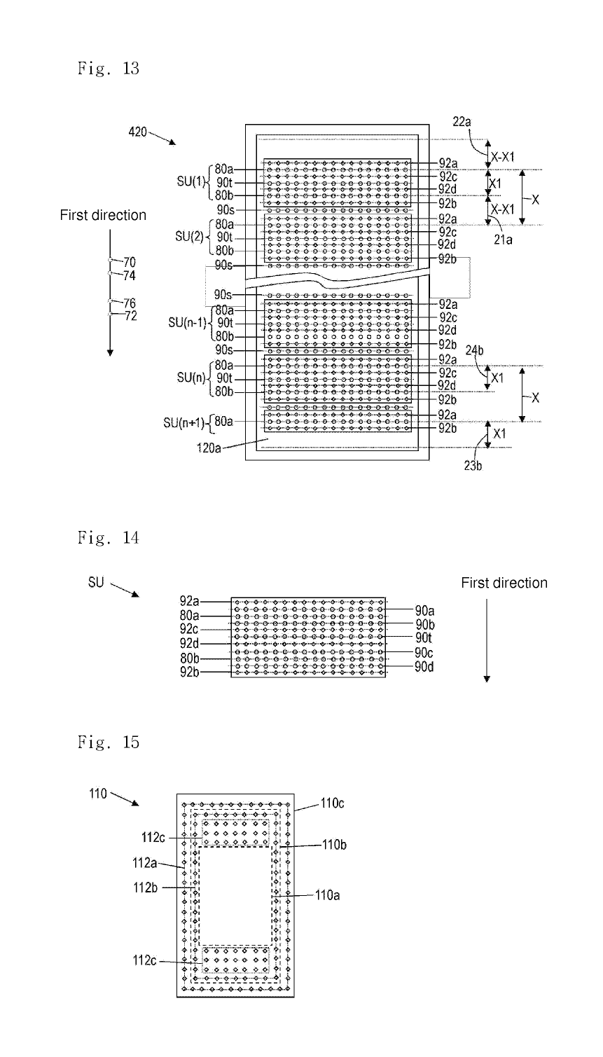

According to an embodiment of the invention, at least one of first, second, third and fourth hole arrays 90a-90d for injecting the purge gas may be added to the injection unit (SU) described with reference to FIG. 11. FIG. 14 is a bottom view of the injection unit (SU) with the additional hole arrays 90a-90d for injecting the purge gas. The first hole array 90a is disposed between the first hole array 92a for exhaust and the hole array 80a for injecting the first materials, the second hole array 90b is disposed between the third hole array 92c for exhaust and the hole array 80a for injecting the first materials, the third hole array 90c is disposed between the fourth hole array 92d for exhaust and the hole array 80b for injecting the second materials, and the fourth hole array 90d is disposed between the second hole array 92b for exhaust and the hole array 80b for injecting the second materials.

The first materials injected from the hole array 80a is exhausted through at least one of the first and third hole arrays 92a and 92c together with the purge gas injected from the hole arrays 90a and 90b which are adjacent to the hole array 80a. The second materials injected from the hole array 80b is exhausted through at least one of the second and fourth hole arrays 92b and 92d together with the purge gas injected from the hole arrays 90c and 90d which are adjacent to the hole array 80b. The purge gas injected from the hole array 90t is exhausted through at least one of the third and fourth hole arrays 92c and 92d.

The injection unit (SU) described with reference to FIG. 14 can be used at the showerhead 120 and 420 described with reference to FIGS. 11 and 13.

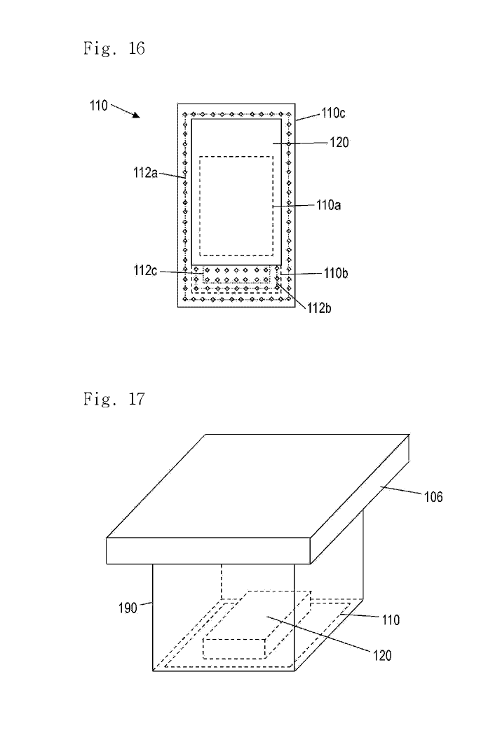

Referring to FIGS. 15 and 16, the substrate support 110 according to an embodiment of the invention is described. FIG. 15 is a top view of the substrate support 110 without the showerhead 120. FIG. 16 is a top view of the substrate support 110 with the showerhead 120 located at the first location 70.

The substrate support 110 comprise a first region inside of 110a which the substrate 50 is placed on and is in contact with the substrate, a second region outside of 110a and inside of 110b which is covered by the showerhead 120 while the showerhead 120 is moved between the first and second locations 70 and 72, and a third region outside of 110b and inside of 110c which is not covered by the showerhead 120. The heating element to heat the substrate may be embedded in the first region of the substrate support 110 and the cooling line may be embedded in the second and third regions to cool down the second and third regions.

A hole array 112a for exhaust may be disposed on the third region along the boundary with the second region such that the hole array 112a surrounds the second region. The hole array 112a is configured to exhaust foreign materials which can come into inside of the showerhead 120 from outside of the showerhead 120 or the source and reactant precursors which can leak from the showerhead 120 to outside of the showerhead 120.

A hole array 112b for exhaust may be disposed adjacent to the third boundary on the second region along the boundary with the third region. A hole array 112c for exhaust can be disposed on the other region of the second region. The hole arrays 112b and 112c are configured to exhaust the source and reactant precursors which can leak from the showerhead 120 to outside of the showerhead 120.

According to an embodiment of the invention, the hole array 112b for exhaust disposed on the second region may be replaced with a hole array for injecting the purge gas. The purge gas injected from the hole array 112b may supply the purge gas required by the showerhead 120 or can be used to prevent the second region of the substrate support 110 from being contaminated with the source and reactant precursors.

According to an embodiment of the invention, the hole array 112c for exhaust disposed on the second region may be replaced with a hole array for injecting the purge gas. The purge gas injected from the hole array 112c may supply the purge gas required by the showerhead 120 or can be used to prevent the second region of the substrate support 110 from being contaminated with the source and reactant precursors.

Referring to FIGS. 17 and 18, a protecting chamber 190 to protect the showerhead 120 and the substrate support 110 is described. FIG. 17 is a perspective three dimensional view of the protecting chamber 190. FIG. 18 is a cross sectional view of the ALD apparatus 100 with the protecting chamber 190.

The protecting chamber 190 is coupled to the showerhead support 106. The protecting chamber 190 comprises a side wall, which extends from the showerhead support 106 towards the substrate support 110. A bottom face of the protecting chamber 190 is open to the substrate support 110. The protecting chamber 190 coupled to the showerhead support 106 can move vertically as the showerhead support 106 moves vertically. The protecting chamber 190 can approach to the showerhead 120 and the substrate support 110 through the opened bottom face.

As illustrated in FIG. 18, the protecting chamber 190 may be configured to move down such that the lower end of the protecting chamber 190 is located about or inside the hole array 109 for exhaust which is disposed between the lower frame 102 of the ALD apparatus 100 and the substrate support 110. The hole for exhaust 109 is disposed along the surroundings of the substrate support 110 and connected to a vacuum pump. The purge gas injected from the hole 150 for injecting the gas is isolated from the outside by the protecting chamber 190 and the purge gas is exhausted through the hole 109 for exhaust.

The ALD apparatus 100 may further comprise an outer chamber 105 as illustrated in FIG. 18. The outer chamber provides a closed space between the upper frame 104 and the lower frame 102. The substrate support 110, the shafts 103, the showerhead support 106 and the showerhead 120 are disposed inside the outer chamber 105. A door not illustrated may be disposed at the outer chamber 105 for transferring the substrate.

Although specific embodiments of the invention have been described and illustrated, the invention is not to be limited to the specific forms or arrangements of parts so described and illustrated. The scope of the invention is to be defined by the claims appended hereto and their equivalents. For example, the invention can be used to deposit the atomic layers on other objects as well as the semiconductor substrate. Although the invention has been described to deposit the atomic layers on a rectangular substrate, the invention can be used for substrate having other shapes. In case that the substrate is circular, for example, both ends 120r of the showerhead 120 or the injection surface 120a may be configured to have arc shape as illustrated in FIG. 19, which is a bottom view of the showerhead 120 configured to deposit the atomic layers on the circular substrate 50. Even though the hole array 92 for exhaust and the hole array 90 for injecting the purge gas have not been illustrated in the injection unit (SU) used in the showerhead 120 of FIG. 19, the injection unit (SU) described with reference to FIGS. 11 and 14 may be used as the injection unit (SU) in the showerhead 120 of FIG. 19.

The invention has been described to deposit the atomic layers with the showerhead 120 moving back and forth linearly. However, the atomic layers can be also deposited by pivoting the showerhead 120 back and forth instead of the linear moving.

Referring to FIGS. 20 and 21, an apparatus and a method to deposit the atomic layers by the pivoting back and forth motions are described. FIG. 20 is a top view of the ALD apparatus 500 comprising a pivoting back and forth mechanism. FIG. 21 is a cross sectional view of the cross section 510 of the ALD apparatus illustrated in FIG. 20. The ALD apparatus 500 comprises a pivoting showerhead 520, which is disposed over the substrate support 110. One end 520a of the pivoting showerhead 520 is coupled to a shaft 524 and the shaft 524 is pivotably coupled to a frame of the ALD apparatus 500 such as the lower frame 102. The shaft 524 is coupled to a pivoting device not illustrated in FIGS. 20 and 21 such that the shaft 524 can pivot about a vertical axis 530.

The opposite end 520b of the showerhead 520 extends from the shaft 524 through an edge of the substrate close to the shaft 524 to about an opposite edge of the substrate. Therefore a length between the both ends of the showerhead 520 is configured to be greater than a diameter or a width of the substrate 50.

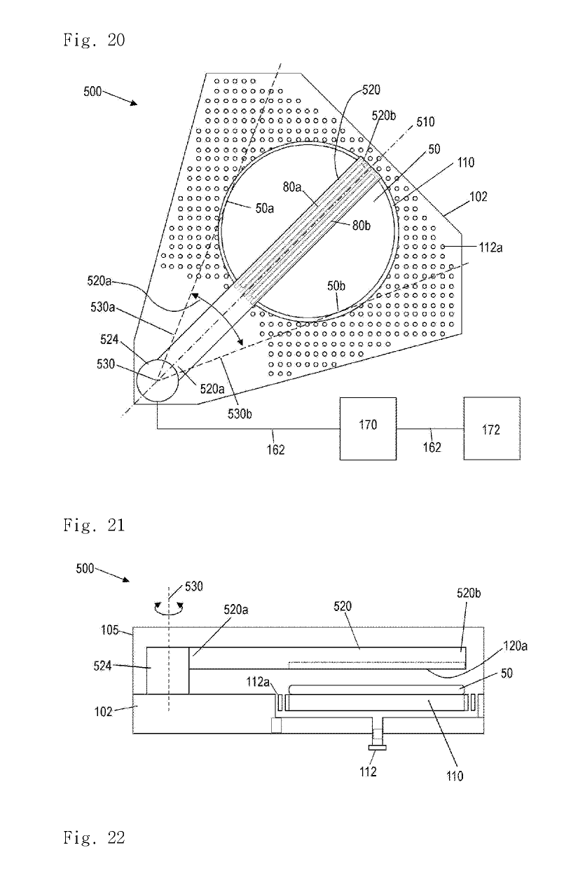

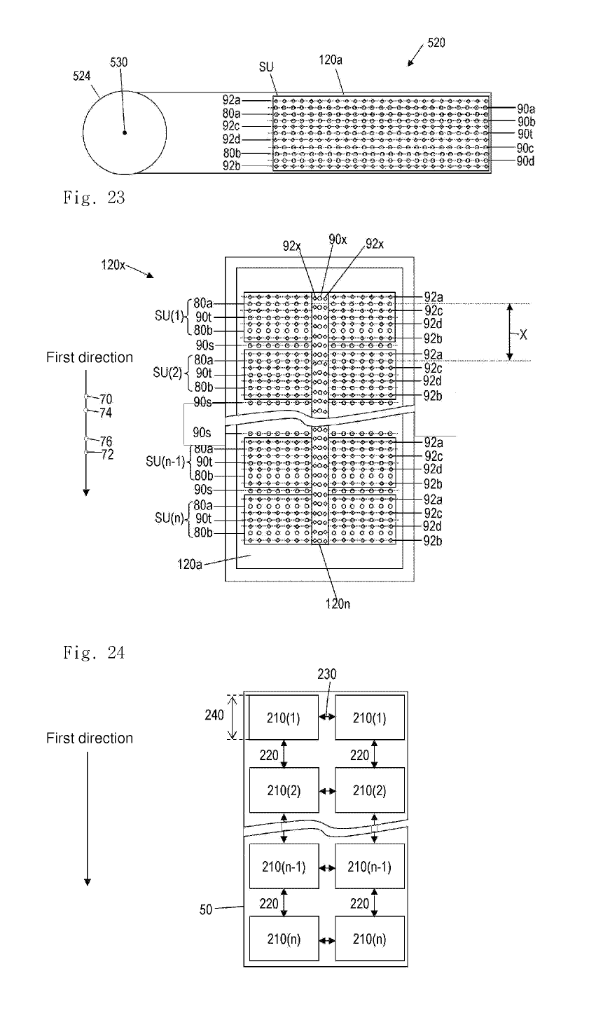

An injection surface 120a is disposed on a bottom surface of the showerhead 520. On the injection surface 120a, at least one injection unit (SU) described with reference to FIG. 14 is disposed. A bottom view of the showerhead 520 having the injection unit described with reference to FIG. 14 is illustrated in FIG. 22. The injection unit (SU) is disposed on the injection surface 120a such that hole arrays of the injection unit (SU) are disposed along the length direction of the showerhead 520. The injection unit (SU) is connected to the gas injection control system 170, the source and reactant precursors 172, the purge gas 172 and the exhaust pump 172, which were described with reference to FIGS. 3 and 4.

The showerhead 520 can be reciprocated between first and second angular locations 530a and 530b by pivoting the shaft 524 about the vertical axis 530. An angle between the first and second angular locations may be smaller than 90 degrees. The first angular location 530a is the location where the source precursor injected from the hole array 80a of the showerhead 520 and the reactant precursor injected from the hole array 80b of the showerhead 520 can coat an edge 50a of the substrate 90. The second angular location 530b is the location where the source precursor injected from the hole array 80a of the showerhead 520 and the reactant precursor injected from the hole array 80b of the showerhead 520 can coat an opposite edge 50b of the substrate 90. At the first angular location 520a, the hole array 80a or the hole array 80b may be aligned to the edge 50a. At the second angular location 520b, the hole array 80a or the hole array 80b may be aligned to the edge 50b.

Around the substrate support 110 of the ALD apparatus 500, multiple holes 112a for exhaust are disposed. The holes 112a for exhaust are configured to exhaust the source and reactant precursors and the purge gas injected from the injection surface 120a of the showerhead 520. The pivoting showerhead 520 may be disposed such that a gap between the surface of the substrate 50 and the injection surface 120a of the showerhead 520 is between 0.1 mm and 30 mm. The substrate support 110 and the pivoting showerhead 520 may be disposed in the chamber 105 as illustrated in FIG. 21.

Referring to FIGS. 20 and 22, a method of depositing the atomic layers by using the showerhead 520 comprises the following steps.

(1) a first pivoting step wherein the showerhead 520 is pivoted from the first angular location 520a to the second angular location 520b,

(2) a source precursor injection step during the first pivoting step wherein the source precursor is injected to the substrate 50 through the hole array 80a of the showerhead 520 but supply of the reactant precursor through the hole array 80b of the showerhead 520 is cut off,

(3) a purge step during the first pivoting step wherein the purge gas is injected to the substrate 50 through at least one hole array 90t of the showerhead 520,

(4) an exhaust step during the first pivoting step wherein the source precursor and the purge gas are exhausted through at least one of the hole arrays 92a-92d for exhaust of the showerhead 520,

(5) a second pivoting step wherein the showerhead 520 is pivoted back from the second angular location 520b to the first angular location 520a,

(6) a reactant precursor injection step during the second pivoting step wherein the reactant precursor is injected to the substrate 50 through the hole array 80b of the showerhead 520 but supply of the source precursor through the hole array 80a of the showerhead 520 is cut off,

(7) a purge step during the second pivoting step wherein the purge gas is injected to the substrate 50 through the at least one hole array 90t of the showerhead 520, and

(8) an exhaust step during the second pivoting step wherein the reactant precursor and the purge gas are exhausted through the at least one of the hole arrays 92a-92d for exhaust of the showerhead 520,

Another method of depositing the atomic layers by using the showerhead 520 comprises the following steps.

(1) the first pivoting step wherein the showerhead 520 is pivoted from the first angular location 520a to the second angular location 520b,

(2) the source precursor injection step during the first pivoting step wherein the source precursor is injected to the substrate 50 through the hole array 80a of the showerhead 520 but the supply of the reactant precursor through the hole array 80b of the showerhead 520 is cut off,

(3) the purge step during the first pivoting step wherein the purge gas is injected to the substrate 50 through the at least one hole array 90t of the showerhead 520,

(4) the exhaust step during the first pivoting step wherein the source precursor and the purge gas are exhausted through the at least one of the hole arrays 92a-92d for exhaust of the showerhead 520,

(5) the second pivoting step wherein the showerhead 520 is pivoted back from the second angular location 520b to the first angular location 520a,

(6) a purge step during the second pivoting step wherein the purge gas is injected to the substrate 50 through the at least one hole array 90t but the supplies of the source and reactant precursors through the hole array 80a and 80b of the showerhead 520 are cut off,

(7) an exhaust step during the second pivoting step wherein the purge gas is exhausted through at least one of the hole arrays 92a-92d for exhaust of the showerhead 520,

(8) a third pivoting step wherein the showerhead 520 is pivoted again from the first angular location 520a to the second angular location 520b,

(9) a reactant precursor injection step during the third pivoting step wherein the reactant precursor is injected to the substrate 50 through the hole array 80b of the showerhead 520 but the supply of the source precursor through the hole array 80a of the showerhead 520 is cut off,

(10) a purge step during the third pivoting step wherein the purge gas is injected to the substrate 50 through the at least one hole array 90t of the showerhead 520, and

(11) an exhaust step during the third pivoting step wherein the reactant precursor and the purge gas are exhausted through the at least one of the hole arrays 92a-92d for exhaust of the showerhead 520.

The showerhead 120 described with reference to FIG. 11 may comprise at least one purge gas injection surface 120n as illustrated in FIG. 23. FIG. 23 is a bottom view of the showerhead 120x comprising the purge gas injection surface 120n. The purge gas injection surface 120n is disposed on the injection surface 120a such that it extends along the first direction from an edge of the injection surface 120a to the opposite end. The purge gas injection surface comprises a hole 90x for injecting the purge gas and does not comprise holes for injecting the source and reactant precursors. The purge gas injection surface may further comprise a hole 92x for exhaust. The hole array 92x for exhaust may be disposed along the periphery of the purge gas injection surface 120n parallel to the first direction. The hole array 90X for injecting the purge gas may be disposed between the hole arrays 92x for exhaust.

The atomic layers are not deposited on a surface of the substrate corresponding to the purge gas injection surface 120n because the source and reactant precursors are not injected to the surface. It is possible not to deposit the atomic layers on a specific region 50a of the substrate 50 not illustrated in FIG. 23 by disposing the purge gas injection unit 120n such that it is aligned to the specific region.

According to an embodiment of the invention, the purge gas injection surface 120n may be configured not to inject any gas by not comprising the hole 90x for injecting the purge gas and the hole 92x for exhaust.

According to an embodiment of the invention, the purge gas injection surface 120n may be configured to comprise only the hole 92x for exhaust.

A width, a location and a number of the purge gas injection surface 120n may be adjusted according to a shape and a location of the specific region 50a.

Turning back to FIG. 23, an embodiment of the invention to deposit the atomic layers by using the showerhead 120x comprises the following steps.

(1) a first moving step wherein the showerhead 120x is moved along the first direction from the first location 70 to the second location 72,

(2) a source precursor injection step during the first moving step wherein the supplies of the source and reactant precursors through the hole arrays 80a and 80b of the injection units (SU) are cut off while the showerhead 120x is moved from the first location 70 to the third location 74, and wherein the source precursor is injected through the hole array 80a but the supply of the reactant precursor through the hole array 80b is still cut off while the showerhead 120 is moved from the third location 74 to the second location 72.

(3) a purge step during the first moving step wherein the purge gas is injected to the substrate 50 through the at least one hole array 90s and 90t of the injection units SU,

(4) an exhaust step during the first moving step wherein the source precursor and the purge gas are exhausted through at least one of the hole arrays 92a-92d for exhaust of injection units SU,

(5) a second moving step wherein the showerhead 120x is moved from the second location 72 to the first location 70,

(6) a reactant precursor injection step during the second moving step wherein the supplies of the source and reactant precursors through the hole arrays 80a and 80b of the injection units (SU) are cut off while the showerhead 120x is moved from the second location 72 to the fourth location 76, and wherein the reactant precursor is injected through the hole array 80b but the supply of the source precursor through the hole array 80a is still cut off while the showerhead 120 is moved from the fourth location 76 to the first location 70.

(7) a purge step during the second moving step wherein the purge gas is injected to the substrate 50 through the at least one hole array 90s and 90t of the injection units SU,

(8) an exhaust step during the second moving step wherein the reactant precursor and the purge gas are exhausted through the at least one of the hole arrays 92a-92d for exhaust of injection units SU,

According to the embodiment, the atomic layers are deposited only when the showerhead 120x is located between the third and fourth locations 74 and 76. The atomic layers are not deposited when the showerhead 120x is located between the first and third locations 70 and 74 or between the second and fourth locations 72 and 76 because both of the source and reactant precursors are required to deposit the atomic layers.

According to the embodiment, the third location 74 is between the first and second locations 70 and 72. It may be closer to the first location 70 or coincides with the first location 70.

According to the embodiment, the fourth location 76 is between the first and second locations 70 and 72. It may be closer to the second location 72 or coincides with the second location 72.

According to the embodiment, it is possible to inject the source and reactant precursors to a part of the substrate instead of the whole surface by making the moving distance of the showerhead 120x, which is the distance between the first and second locations 70 and 72, smaller than the distance X between the neighboring hole arrays 80a for injecting the source precursor of the injection units SU.

According to the embodiment, the purge gas can be injected through the purge gas injection surface 120n but the source and reactant precursors are not injected.

According to the embodiment, only the exhaust is carried out through the purge gas injection surface 120n but the source and reactant precursors are not injected.

According to the embodiment, the purge gas can be injected and the exhaust can be carried out through the purge gas injection surface 120n but the source and reactant precursors are not injected.

Referring to FIG. 24, a shape of the atomic layers which can be deposited on the substrate 50 by using the showerhead 120x illustrated in FIG. 23 is described. FIG. 24 is a top view of the substrate 50.

On the substrate 50, a first region 210(1) deposited by the first injection unit SU(1) of the showerhead 120x, a second region 210(2) deposited by the second injection unit SU(2) of the showerhead 120x, . . . , a (n−1)'th region 210(n−1) deposited by the (n−1)'th injection unit SU(n−1) of the showerhead 120x, and a n'th region 210(n) deposited by the n'th injection unit SU(n) of the showerhead 120x are formed. For example, only the first region 210(1) is formed in case that the showerhead 120x comprises only the first injection unit SU(1).

A width 240 of the atomic layers 210 along the first direction is determined by the distance between the third and fourth locations 74 and 76 which were described with reference to FIG. 23. The regions 210 are separated each other. The separation 220 along the first direction is the separation made by the embodiment described with reference to FIG. 23 and the separation 230 along the direction perpendicular to the first direction is the separation made by the purge gas injection surface 120n of the showerhead 120x. The separation 220 along the first direction can be controlled by adjusting the distance between the third and fourth locations 74 and 76. The separation 230 along the perpendicular direction can be controlled by adjusting the width, configuration and shape of the purge gas injection surface 120n of the showerhead 120x. According to the embodiment, it is possible to deposit the atomic layers selectively on the specific regions of the substrate 50 without using the shadow mask.

Although specific embodiments of the invention have been described and illustrated, the invention is not to be limited to the specific forms or arrangements of parts so described and illustrated. The scope of the invention is to be defined by the claims appended hereto and their equivalents.

1-66. (canceled)

67. A method for depositing atomic layers comprising:
disposing a substrate on a substrate support;
disposing a showerhead about said substrate such that said substrate faces said showerhead wherein said showerhead comprises within is a periphery of said showerhead an injection surface which comprises a hole for injecting source precursor, a hole for injecting reactant materials, a hole for injecting purge gas and a hole for exhaust; and
depositing said atomic layers by moving said showerhead back and forth relative to said substrate repeatedly between first and second locations along a first direction and supplying said source and reactant precursors to said substrate,
wherein said source and reactant precursors are not supplied at the same time to said substrate while said substrate or said showerhead moves in the same direction during said repeated back and forth movings between said first and second locations.

68. The method of claim 67 wherein a first reaction layer is formed on said substrate while only said source precursor is supplied, and a second reaction layer is formed on said substrate while only said reactant precursor is supplied, said second reaction layer being formed by a reaction of said reactant precursor with said first reaction layer.

69. The method of claim 67 wherein only said source precursor is supplied during said moving from said first location to said second location, and only said reactant precursor is supplied during said moving from said second location to said first location.

70. The method of claim 67 wherein said source and reactant precursors are supplied alternately during said repeated moving from said first location to said second location.

71. The method of claim 70 wherein said purge gas is supplied and exhausted during said moving from said second location to said first location

72. The method of claim 67 wherein only said purge gas is supplied and exhausted without supplying said source and reactant precursors while said substrate or said showerhead changes its moving direction.

73. The method of claim 67 wherein said showerhead reciprocates relative to said substrate linearly or pivotably between said first and second locations,

74. The method of claim 67 wherein said purge gas is supplied to said substrate at the same time while said source precursor or said reactant precursor is supplied, and said purge gas is exhausted at the same time with said source or reactant precursor.

75. The method of claim 67 wherein a relative moving speed of said showerhead along said first direction is different from a relative moving speed of said showerhead along said reverse direction of said first direction.

76. The method of claim 67 wherein at least a first part of said substrate which said source precursor or said reactant precursor is supplied to during said moving from said first location to said second location is overlapped with at least a second part of said substrate which said source precursor or said reactant precursor is supplied to during said moving from said second location to said first location.

77. The method of claim 76 wherein said first part is overlapped with said second part between said first and said second locations.

78. The method of claim 76 wherein said first part is overlapped with said second part between said first location and a third location, said third location being disposed between said first and second locations.

79. The method of claim 76 wherein said first part is overlapped with said second part between said second location and a third location, said third location being disposed between said first and second locations.

80. The method of claim 76 wherein said first part is overlapped with said second part between third and fourth locations, said third and fourth locations being disposed between said first and second locations.

81. A method for depositing atomic layers comprising:
disposing a substrate on a substrate support;
disposing a showerhead about said substrate such that said substrate faces said showerhead wherein said showerhead comprises within a periphery of said showerhead at least two injection units disposed along a first direction, each of said injection unit comprising at least one hole for injecting source precursor, at least one hole for injecting reactant materials, at least one hole for injecting purge gas, and at least one hole for exhaust; and
depositing said atomic layers by moving said showerhead back and forth relative to said substrate along a first direction and a reverse of said first direction,
wherein a distance of said relative moving of said showerhead is equal to or smaller than a half of a width of said substrate along said first direction.

82. The method of claim 81 wherein said distance of said relative moving is equal to or smaller than 1/n of said width of said substrate along said first direction, said injection surface of said showerhead comprising at least two similar injection units disposed along said first direction.

83. The method of claim 81 comprising depositing said atomic layers by moving said showerhead relative to said substrate repeatedly between first and second locations along said first and reverse directions, wherein said source and reactant precursors are not supplied to said substrate at the same time while said substrate or said showerhead moves in the same direction during said repeated movings.

84. The method of claim 81 wherein said purge gas is supplied through said hole for injecting said reaction precursor while said source precursor is supplied, and said purge gas is supplied through said hole for injecting said source precursor while said reactant source precursor is supplied.

85. The method of claim 83 wherein said source and reactant precursors are supplied alternately during said movings from said first location to said second location.

86. The method of claim 83 wherein at least a first part of said substrate which said source precursor or said reactant precursor is supplied to during said moving from said first location to said second location is overlapped with at least a second part of said substrate which said source precursor or said reactant precursor is supplied to during said moving from said second location to said first location.

87. The method of claim 67 wherein said substrate reciprocates within said periphery of said showerhead along said first direction.

88. The method of claim 81 wherein said substrate reciprocates within said periphery of said showerhead along said first direction.

89. The method of claim 81 wherein a moving distance of said substrate or said showerhead along said first direction between said first and second locations corresponds to a width of said injection unit along said first direction.
